(19) United States
(12) Patent Application Publication
(10) Pub. No.: US 2017/0117890 A1
(43) Pub. Date: Apr. 27, 2017

(54) CIRCUIT, METHOD OF CONTROLLING A CIRCUIT AND DEVICE

(71) Applicant: FUJITSU LIMITED, Kawasaki-shi (JP)

(72) Inventor: Kouichi KANDA, Chofu (JP)

(73) Assignee: FUJITSU LIMITED, Kawasaki-shi (JP)

(21) Appl. No.: 15/291,704

(22) Filed: Oct. 12, 2016

(30) Foreign Application Priority Data
Oct. 23, 2015 (JP) 2015-209419

(51) Int. Cl. H03K 17/22; H03K 19/0948; H02J 7/00; H03K 19/20

(52) U.S. Cl. CPC H03K 17/223; H03K 19/20; H03K 19/0948; H02J 7/0063; H02J 7/345

(57) ABSTRACT

A circuit includes a power wire, a switch element coupled to the power wire, an internal circuit coupled to the power wire via the switch element, a signal generation circuit coupled to the power wire and configured to generate a control signal based on a first reset signal outputted for a first period after power supply from a power source to the power wire starts, and a gate element configured to control the switch element based on the control signal and a second reset signal outputted for a second period longer than the first period after the power supply to the power wire starts.

### CROSS-REFERENCE TO RELATED APPLICATION

This application is based upon and claims the benefit of priority of the prior Japanese Patent Application No. 2015-209419, filed on Oct. 23, 2015, the entire contents of which are incorporated herein by reference.

### FIELD

The embodiments discussed herein are related to a circuit, a method of controlling a circuit and a device.

### BACKGROUND

For a device driven with a power supplied from a battery, such as, for example, an wearable device like a sensor attached to the human body, there is a demand to extend the operable time of the device by the battery. To achieve this, it is desired to reduce the power consumed in an electronic circuit formed as a semiconductor chip, such, for example, as a central processing unit (CPU) and a memory. Meanwhile, there has been developed a device using a power supply source formed of a power generation element converting natural energy to power, such as a power supply source. Currently, however, the harvester power supply may not be said to have sufficient power supply capacity. Consequently, when the power consumed in an electronic circuit exceeds power which may be provided by the harvester power supply, the potential of the power wire for supplying power to the electronic circuit drops and thereby the electronic circuit may malfunction. Therefore, as in the case where the battery is used as a power supply source, a technique for reducing the power consumed in the electronic circuit is desired.

An example of a circuit element forming the electronic circuit is a complementary metal oxide semiconductor (CMOS) inverter. FIG. 1A is a diagram illustrating a circuit configuration of the CMOS inverter, and FIG. 1B is a diagram illustrating a circuit configuration example of a memory cell of a static random access memory (SRAM) using the CMOS inverter. As illustrated in FIG. 1A, the CMOS inverter includes a P type MOS transistor PM1 and an N type MOS transistor NM1, which are connected in series and disposed between a power wire PW and a grounding wire GND. When an input potential to the CMOS inverter is a high potential (hereinafter referred to as the H level) higher than a threshold potential, the P type MOS transistor PM1 is turned off and the N type MOS transistor NM1 is turned on, and thereby an output potential of the CMOS inverter is a low potential (hereinafter referred to as the L level). On the other hand, when the input potential to the CMOS inverter is at the L level lower than the threshold potential, the P type MOS transistor PM1 is turned on and the N type MOS transistor NM1 is turned off, and thereby the output potential of the CMOS inverter is at the H level. In the CMOS inverter, whether the input potential is at the H level or the L level, any one of the P type MOS transistor PM1 and the N type MOS transistor NM1 is turned off. Therefore, ideally, through-current does not flow between the power wire PW and the grounding wire GND.

However, at a time just after power supply to the electronic circuit is started, there may be a situation where the potential of the power wire PW does not rise enough, and the potential of the power wire PW and the input potential of the CMOS inverter are intermediate potentials between the H level and the L level. In this case, both the P type MOS transistor PM1 and the N type MOS transistor NM1 may not be fully turned off. In this state, a current path exists between the power wire PW and the grounding wire GND, and through-current is generated between the power wire PW and the grounding wire GND.

Meanwhile, as illustrated in FIG. 1B, one cell of the SRAM has a configuration in which two CMOS inverters are combined to hold data. When power supply to the electronic circuit starts, a through-current may flow into the CMOS inverters as mentioned above, and dispensable through-current may be generated even in the SRAM which includes the CMOS as a main component. If through-current is generated in each cell of a SRAM including many cells, a large through-current flows in the SRAM as a whole. In a device driven with a power supply source formed of a power generation element, such as the battery and the harvester power supply, it is desirable to reduce the through-current which may be generated when power supply starts.

Another problem which may happen at the start of power supply to an electronic circuit is that the electronic circuit may perform dispensable operation due to unsettlement of the logical value (H level or L level) of the output signal of a circuit element such as a flip-flop circuit. FIG. 2 is a diagram illustrating an example of a logical circuit included in the electronic circuit. FIG. 2 illustrates an example of a logical circuit including an inverter, combinational circuits such as a NAND circuit and a NOR circuit, and sequential circuits such as flip-flop circuits. When power supply to the electronic circuit starts, the logical value outputted from each circuit element is not settled to a predetermined value and the logical value is passed to the circuit elements in the later stages, in turn. This may cause the circuit elements in the later stages to perform dispensable operation and thereby the electronic circuit may consume dispensable power as a whole.

As a method for solving those problems which may happen at the start of power supply to the electronic circuit, there is a technique called a power-on reset. FIGS. 3A and 3B are diagrams for describing the power-on reset. FIG. 3A is a diagram illustrating an electronic circuit which performs reset operation by using the power-on reset at the start of power supply. As illustrated in FIG. 3A, a power supply 100 and an electronic circuit 200 are coupled to each other via a power wire PW, and a time constant circuit 110 including a resistance element R0 and a capacity element C0 is provided to the power wire PW. A reset signal rc outputted from the time constant circuit 110 is supplied to the electronic circuit 200.

FIG. 3B is a diagram illustrating changes in the potential of the power wire PW and the potential of the reset signal rc at the start of power supply to the electronic circuit 200. Here, assume that the potential of the power wire PW during normal operation of the electronic circuit 200 is 1.8 V. First, the power supply to the power wire PW is started by the power supply 100, and the potential of the power wire PW rises from 0 V to 1.8 V. Thereafter, the potential of the reset signal rc gradually rises based on a time constant of the time constant circuit 110 and becomes close to 1.8 V as time elapses. Vth indicated in FIG. 3B represents a threshold voltage for the reset signal rc. The electronic circuit 200 recognizes the reset signal rc as an L level signal until the potential of the reset signal rc reaches the threshold voltage Vth. Then, an internal circuit of the electronic circuit 200 is maintained in the reset mode based on the reset signal rc of the L level. In the reset mode, for example, power supply to the CMOS inverter and other circuit elements of the electronic circuit 200 is shut off, or the output signal of circuits of the electronic circuit 200 such as a flip-flop circuit is fixed to a predetermined logical value. Thus, in the reset mode, leak current in the electronic circuit 200 is suppressed, or dispensable operation of the logical circuits of the electronic circuit 200 is restricted. As an example of prior arts, Japanese Laid-open Patent Publication Nos. 2000-269788, 2012-230726, and No. 7-78479 are known.

### SUMMARY

According to an aspect of the invention, a circuit includes a power wire, a switch element coupled to the power wire, an internal circuit coupled to the power wire via the switch element, a signal generation circuit coupled to the power wire and configured to generate a control signal based on a first reset signal outputted for a first period after power supply from a power source to the power wire starts, and a gate element configured to control the switch element based on the control signal and a second reset signal outputted for a second period longer than the first period after the power supply to the power wire starts.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are diagrams illustrating a circuit configuration of the CMOS inverter and a circuit configuration of the SRAM cell;

FIG. 2 is a diagram illustrating a configuration example of a logical circuit included in the electronic circuit;

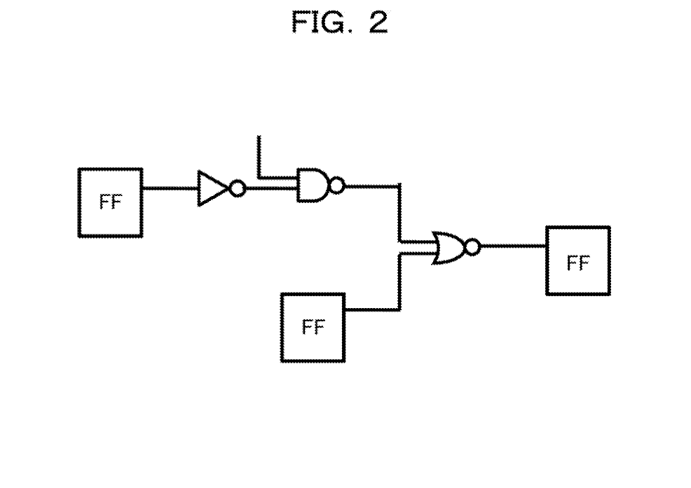

FIGS. 3A and 3B are diagrams for describing the power-on reset;

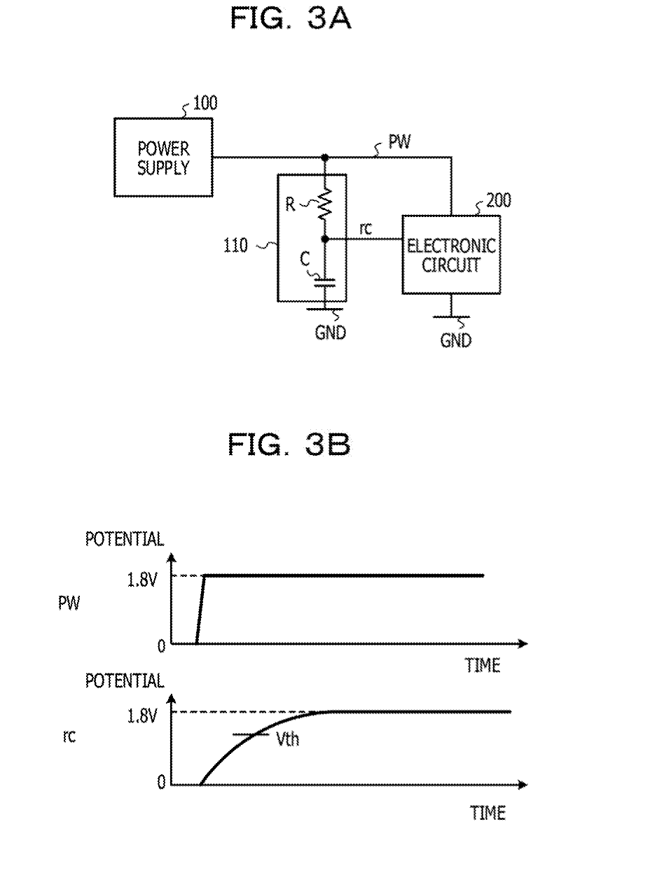

FIGS. 4A and 4B are diagrams illustrating configuration examples of devices including an electronic circuit according to a first embodiment;

FIG. 5 is a diagram illustrating a circuit configuration example of the electronic circuit according to the first embodiment;

FIGS. 6A and 6B are diagrams illustrating a configuration example and a truth table of a flip-flop circuit according to the first embodiment;

FIG. 7 is a timing chart of the electronic circuit illustrated in FIG. 5;

FIG. 8 is a diagram illustrating a configuration example of the electronic circuit according to the first embodiment;

FIG. 9 is a timing chart of the electronic circuit illustrated in FIG. 8;

FIG. 10 is a diagram illustrating a circuit configuration example of a gate element according to the first embodiment;

FIG. 11 is a diagram illustrating a coupling example when a first time constant circuit and a second time constant circuit are commonly provided in multiple electronic circuits;

FIG. 12 is a diagram illustrating a modified example of the electronic circuit according to the first embodiment;

FIGS. 13A and 13B are diagrams illustrating a configuration example of a resistance element of the second time constant circuit according to the first embodiment;

FIG. 14 is a diagram illustrating a circuit configuration example of a SRAM cell array used as a circuit block in the first embodiment;

FIG. 15 is a diagram illustrating a circuit configuration example of an electronic circuit according to a second embodiment;

FIG. 16 is a diagram illustrating a time chart of the electronic circuit according to the second embodiment;

FIG. 17 is a diagram illustrating a method for generating a discharge element control signal according to the second embodiment; and

FIG. 18 is a diagram illustrating a modified example of the electronic circuit according to the second embodiment.

### DESCRIPTION OF EMBODIMENTS

### First Embodiment

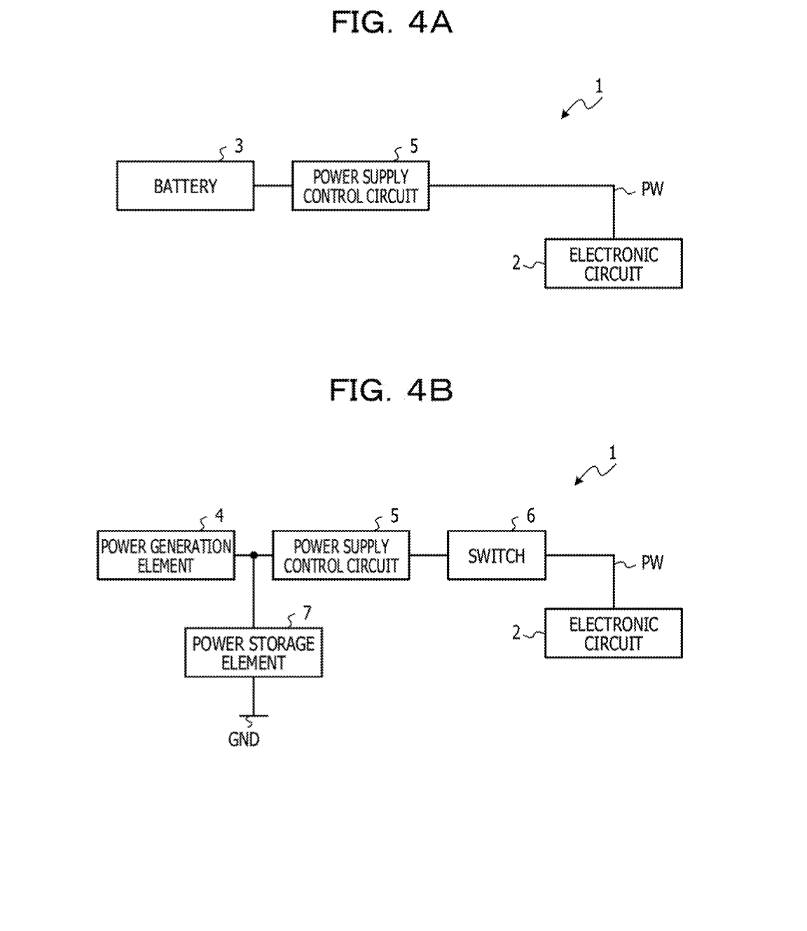

FIGS. 4A and 4B are diagrams illustrating a configuration example of devices including the electronic circuit according to the first embodiment. In FIG. 4A, a device 1 includes an electronic circuit 2, a battery 3, a power supply control circuit 5 and a power wire PW. The battery 3 is a power supply source of the device 1. The power supply control circuit 5 is configured to control a potential of the power wire PW or a current supplied to the power wire PW. The electronic circuit 2 is coupled to the power wire PW and configured to perform a predetermined operation based on the supplied power. In FIG. 4B, the device 1 includes an electronic circuit 2, a power generation element 4, a power supply control circuit 5, a switch 6, a power storage element 7, and a power wire PW. The power generation element 4 is a power supply source of the device 1. The power storage element 7 is configured to store charge generated by the power generation element 4. The switch 6 is configured to control supply or stop of the power to the electronic circuit 2.

Although FIGS. 4A and 4B illustrate only one electronic circuit 2, multiple electronic circuits 2 may be included in the device 1. The electronic circuit 2 includes, for example, a processor such as a CPU and a micro processing unit (MPU), a volatile memory such as a dynamic random access memory (DRAM) and a static random access memory (SRAM), a non-volatile memory such as a flash memory and a ferroelectric random access memory (FeRAM), a sensor such as an acceleration sensor and a temperature sensor, and a radio device such as a radio frequency (RF) device. The battery 3 includes, for example, a lithium ion battery and a nickel-cadmium battery, and the power generation element 4 includes, for example, a harvester power supply utilizing light and heat. The power supply control circuit 5 includes, for example, a switching regulator and a linear regulator. The power storage element 7 includes, for example, a capacitor provided between the power generation element 4 and the grounding wire GND. Although FIGS. 4A and 4B illustrate a device with the battery 3 and the power generation element 4 as a power supply source, the embodiment may be applied to a device using the other power supply such as, for example, a commercial power supply as the power supply source.

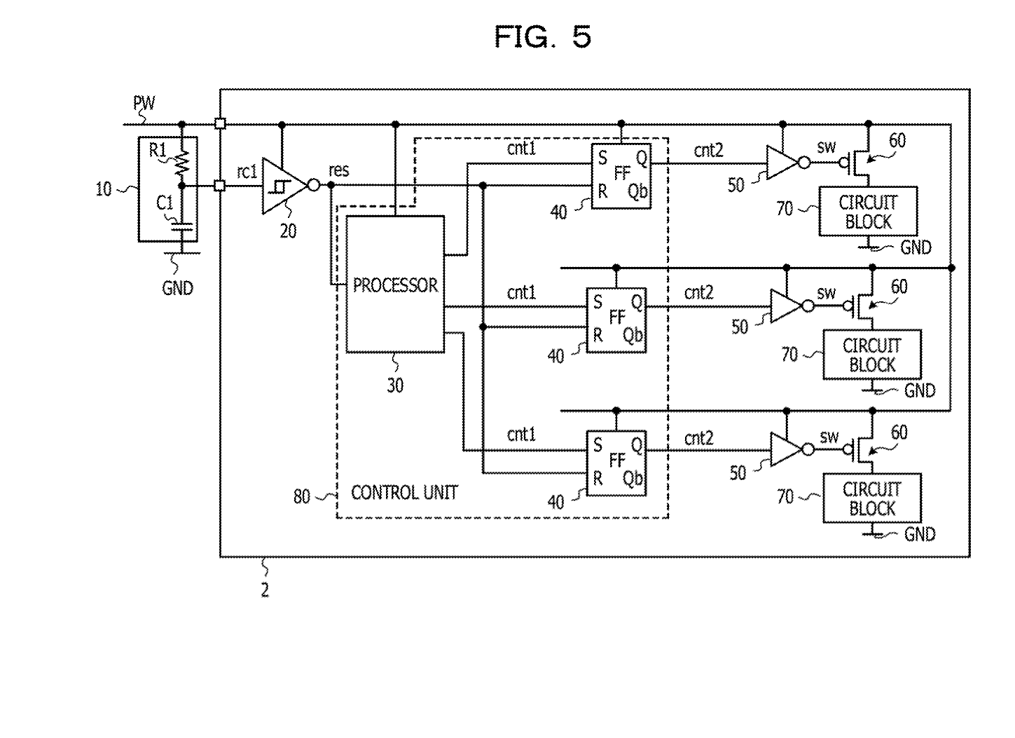

FIG. 5 is a diagram illustrating an example of the circuit configuration of the electronic circuit 2. The electronic circuit 2 includes a Schmitt trigger circuit 20, a processor 30, a flip-flop circuit 40, an inverter 50, a switch element 60 and a circuit block 70. Hereinafter, a circuit portion including the processor 30 and the flip-flop circuit 40 is referred to as a control unit 80. Those element circuits included in the electronic circuit 2 are coupled to the power wire PW, and power is supplied to the power wire PW from the battery 3 or the power generation element 4. A first time constant circuit 10 including a resistance element R1 and a capacity element C1 is coupled to the power wire PW.

The electronic circuit 2 includes three circuit blocks 70, and a switch element 60 is provided in each of circuit blocks 70 so as to allow separate supply and stop of the power to each of circuit blocks 70. In the embodiment, the number of circuit blocks 70 is not limited to three. The circuit block 70 is, for example, a memory cell array including multiple SRAM cells.

Here, names of multiple signals illustrated in FIG. 5 are described. A signal transmitted from the first time constant circuit 10 to the Schmitt trigger circuit 20 is referred to as “first reset signal rc1”, a signal outputted from the Schmitt trigger circuit 20 is referred to as “internal reset signal res”, a signal outputted from the processor 30 is referred to as “internal control signal cnt1”, a signal outputted from the flip-flop circuit 40 is referred to as “control signal cnt2”, and a signal outputted from the inverter 50 receiving the control signal cnt2 is referred to as “switch control signal sw”.

Next, function of each element circuit is described. Although FIG. 5 illustrates three circuit blocks 70 and a configuration allowing separate power supply to the three circuit blocks 70, each of those circuits has an equivalent circuit configuration and control method. As such, one circuit block 70 out of the three circuit blocks 70 and a method for controlling power supply to the circuit block 70 is described.

The first time constant circuit 10 is coupled to the power wire PW and configured to output the first reset signal rc1 with a specific delay added to the potential change of the power wire PW when power supply to the power wire PW is started. In FIG. 5, the first time constant circuit 10 is a RC time constant circuit including a resistance element R1 and a capacity element C1. Time constant of the first time constant circuit 10 is represented by the product of the resistance of the resistance element R1 and the electrostatic capacitance of the capacity element C1. The first time constant circuit 10 may be externally coupled to the electronic circuit 2 or may be provided in the electronic circuit 2 as a part of the integrated circuit.

The Schmitt trigger circuit 20 is coupled to the power wire PW and configured to receive the first reset signal rc1 and generate the internal reset signal res. When power supply to the electronic circuit 2 starts, the Schmitt trigger circuit 20 maintains the internal reset signal res at the H level being the potential of the power wire PW until the potential of the first reset signal rc1 rises from the level of the grounding wire GND and reaches a predetermined threshold level. The internal reset signal res is supplied to the processor 30 and the flip-flop circuit 40. While the internal reset signal res remains at the H level, the processor 30 and the flip-flop circuit 40 are maintained in their initial modes. When the potential of the first reset signal rc1 reaches a threshold level, the Schmitt trigger circuit 20 turns the internal reset signal res to the L level. When the internal reset signal res is turned to the L level, the initial modes of the processor 30 and the flip-flop circuit 40 are cancelled.

The processor 30 is a circuit block configured to control supply and stop of the power to the circuit block 70 by controlling the switch element 60. The processor 30 is coupled to the power wire PW to receive the internal reset signal res from the Schmitt trigger circuit 20. When power supply to the electronic circuit 2 starts, the processor 30 is reset by the internal reset signal res, so that the internal control signal cnt1 being an output signal of the processor 30 is kept at a predetermined logical value. In the normal operation after cancellation of the reset mode, the processor 30 switches the potential level of the internal control signal cnt1 to control the on state and off state of the switch element 60. The processor 30 may be a hard-wired logical circuit or may be a processing unit which implements a predetermined function by executing a computer program. The internal control signal cnt1 is inputted into the flip-flop circuit 40.

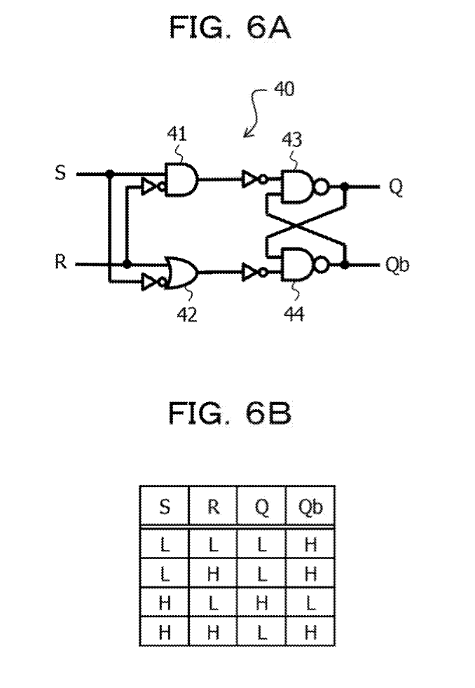

The flip-flop circuit 40 is a circuit block configured to generate the control signal cnt2 based on the internal control signal cnt1. The flip-flop circuit 40 is coupled to the power wire PW to receive the internal control signal cnt1 and the internal reset signal res. The flip-flop circuit 40 includes input terminals of a set terminal S and a reset terminal R, and output terminals Q and Qb. The internal control signal cnt1 transmitted from the processor 30 and the internal reset signal res transmitted from the Schmitt trigger circuit 20 are inputted into the set terminal S and the reset terminal R respectively. When power supply starts or while the internal reset signal res is at the H level, the control signal cnt2 outputted from the output terminal Q of the flip-flop circuit 40 is maintained at the L level irrespective of the logical value of the internal control signal cnt1. The control signal cnt2 is inputted into the inverter 50. Detail of the flip-flop circuit 40 is described later with reference to FIGS. 6A and 6B.

The inverter 50 is coupled to the power wire PW to receive the control signal cnt2 and output the switch control signal sw being an inversion signal of the control signal cnt2. The switch control signal sw is inputted into the switch element 60.

The switch element 60 supplies power to the circuit block 70 or stops power supply to the circuit block 70. The switch element 60 is, for example, a P type MOS transistor and configured to receive the switch control signal sw to a gate electrode of the P type MOS transistor. When the switch control signal sw is at the H level, the switch element 60 is turned off and power supply to the circuit block 70 is stopped. When the switch control signal sw is at the L level, the switch element 60 is turned on and power is supplied to the circuit block 70. When power supply to the electronic circuit 2 starts (in the reset mode), the switch control signal sw is at the H level and the switch element 60 is turned off. Thus, the power is not supplied to the circuit block 70. On the other hand, after the reset mode is cancelled, the control signal cnt2 outputted from the flip-flop circuit 40 is switched between the H level and the L level according to the internal control signal cnt1 outputted from the processor 30, and thereby the on state and the off state of the switch element 60 are controlled.

FIG. 6A is a diagram illustrating a circuit configuration example of a flip-flop circuit 40 according to the first embodiment, and FIG. 6B is a truth table illustrating a correspondence relationship between a logical value of the input signal and a logical value of the output signal of the flip-flop circuit 40. The flip-flop circuit 40 includes an AND circuit 41, an OR circuit 42, a first NAND circuit 43, and a second NAND circuit 44. The flip-flop circuit 40 includes a set terminal S and a reset terminal R as input terminals, and an output terminal Q and an output terminal Qb as output terminals. Assume that the signal outputted from the output terminal Qb is not used in the embodiment.

First, input of the internal reset signal res into the reset terminal R of the H level when power supply starts is described. When the input signal into the reset terminal R is a signal of the H level, a signal of the H level is outputted from the OR circuit 42. Also, a signal of the L level is outputted from the AND circuit 41. Then, irrespective of the logical value of a signal inputted into the set terminal S, a signal of the L level is outputted from the first NAND circuit 43 as the control signal cnt2 being the output of the output terminal Q. The control signal cnt2 of the L level is inverted by the inverter 50 as illustrated in FIG. 5, the switch control signal sw of the H level is inputted into a gate electrode of the switch element 60, and the switch element 60 is turned off.

Next, description is provided for a state where the internal reset signal res being an input signal into the reset terminal R is turned to the L level and the reset mode is cancelled. When the internal reset signal res is turned to the L level, the AND circuit 41 outputs a signal of a logical value identical with a logical value of the internal control signal cnt1 inputted into the set terminal S, and the OR circuit 42 outputs a signal of a logical value being reverse to a logical value of the internal control signal cnt1. For example, if the internal control signal cnt1 inputted into the set terminal S is at the L level, the output terminal Q outputs the control signal cnt2 of the L level. In this case, since the inverter 50 illustrated in FIG. 5 outputs the switch control signal sw of the H level, the switch element 60 is turned off and power is not supplied to the circuit block 70. On the other hand, if the internal control signal cnt1 inputted into the set terminal S is turned to the L level with the reset mode cancelled, the output terminal Q outputs the control signal cnt2 of the H level. In this case, since the inverter 50 outputs the switch control signal sw of the L level, the switch element 60 is turned on and power is supplied to the circuit block 70.

Thus, the first reset signal rd generated by using the first time constant circuit 10 provides a predetermined reset period when power supply starts, and power supply to the circuit block 70 is shut off. As a result, when the potential of the power wire PW rises, leak current generated in the circuit block 70 is suppressed. After the reset period has passed, the processor 30 outputs the internal control signal cnt1 so as to selectively turn on the switch element 60 during a period when the circuit block 70 requests power, and thereby power is supplied to the circuit block 70.

Here, a problem which the inventor of the disclosure has found regarding the circuit illustrated in FIG. 5 is described. In the circuit illustrated in FIG. 5, when power supply starts, the Schmitt trigger circuit 20 outputs the internal reset signal res of the H level during a period when the potential of the power wire PW rises from the L level to the H level and becomes steady. Output of the flip-flop circuit 40 is maintained such that the switch element 60 is turned off by the internal reset signal res of the H level. However, the potential of the power wire PW does not reach the H level from the L level immediately after power supply starts. That is, the potential of the power wire PW increases gradually from the L level and reaches the H level of normal operation and stabilizes after a predetermined time has passed. For example, assuming that the potential of the power wire PW is 1.8 V, the internal reset signal res outputted from the Schmitt trigger circuit 20 is not 1.8V at the beginning of power supply but a potential of the power wire PW. At that timing, for example, the internal reset signal res may be 1.0 V. In such a case, the internal reset signal res outputted from the Schmitt trigger circuit 20 may be determined as being a signal of the H level by the control unit 80 including the processor 30 and the flip-flop circuit 40. Further, even when the internal reset signal res itself is determined as being a signal of the H level, the control signal cnt2 of the L level may not be outputted from the output terminal Q in the flip-flop circuit 40 which operates upon receiving the potential of the power wire PW which has not yet reached 1.8 V. That is, it is considered that in a period when the potential of the power wire PW reaches 1.8 V and stabilizes, operational certainty of the flip-flop circuit 40 is lower than operational certainty in the normal operation.

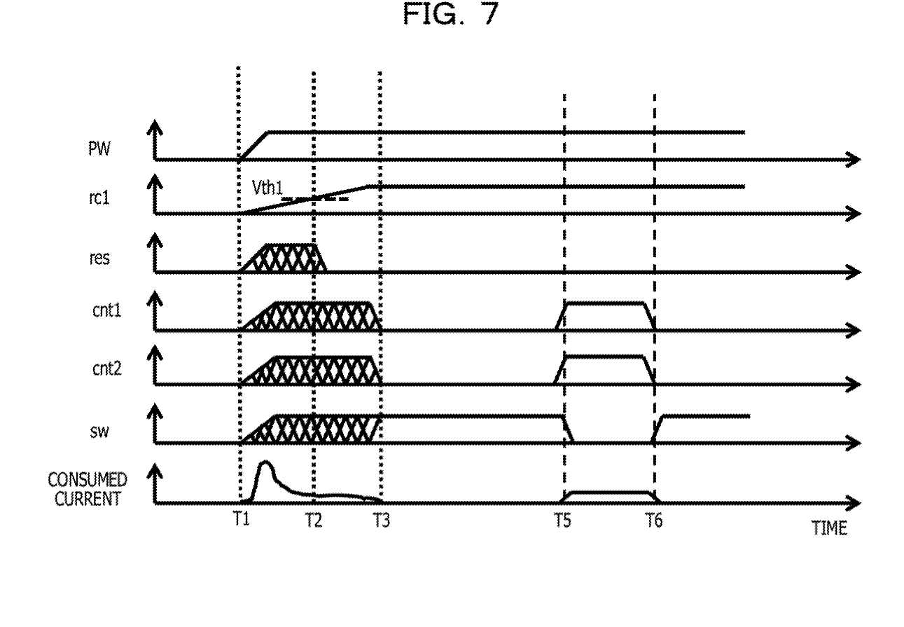

FIG. 7 is a timing chart, in a period from a time T1 to a time T2, for each of a potential of the power wire PW after power supply starts, a potential of the first reset signal rc1 outputted from the first time constant circuit 10, a potential of the internal reset signal res outputted from the Schmitt trigger circuit 20, a potential of the internal control signal cnt1 outputted from the processor 30, a potential of the control signal cnt2 outputted from the flip-flop circuit 40, a potential of the switch control signal sw controlling the switch element 60, and current flowing in the circuit block 70. First, a period from a time T1 to a time T2 is described.

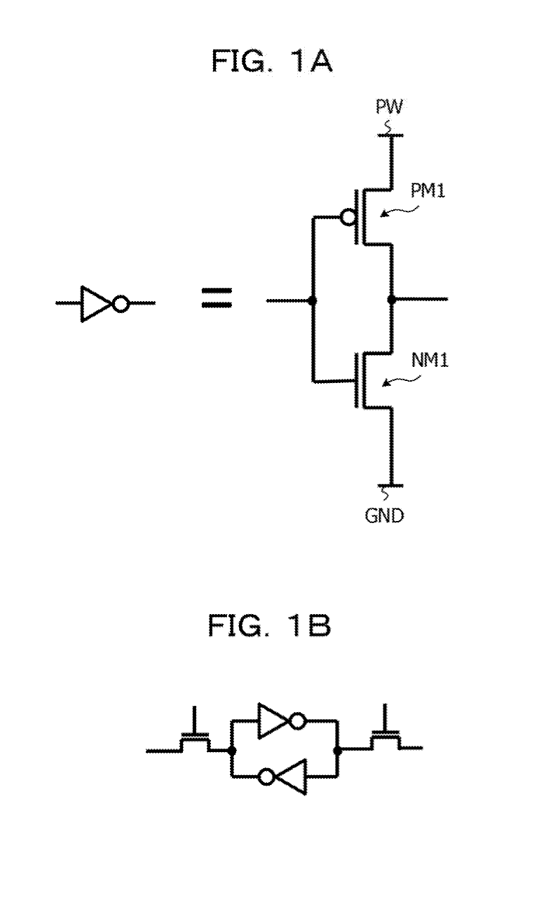

A time T1, power supply to the power wire PW is started and the potential of the power wire PW rises. The potential of the first reset signal rc1 outputted from the first time constant circuit 10 coupled to the power wire PW rises more gradually than the potential of the power wire PW. By the time T2 when the potential of the first reset signal rc1 reaches a threshold voltage Vth1 of the Schmitt trigger circuit 20, the Schmitt trigger circuit 20 outputs the internal reset signal res of the H level. As described above, the potential level of the internal reset signal res outputted by the Schmitt trigger circuit 20 depends on a potential fluctuation of the power wire PW. Therefore, it is uncertain whether the Schmitt trigger circuit 20 may output the internal reset signal res of the H level in a reliable manner. Also, upon receiving power supply, the processor 30 starts arithmetic processing, but may not control the processing result to the H level or the L level in a reliable manner due to uncertainty of the potential of multiple nodes inside the circuit at the beginning of operation. For this reason, the internal control signal cnt1 of an unintended potential level may be outputted from the processor 30. The flip-flop circuit 40 also may output the control signal cnt2 of an unintended potential level due to uncertainty of the internal control signal cnt1 and uncertainty of the internal reset signal res. As a result, the inverter 50, which outputs an inversion signal of the control signal cnt2, also may output the switch control signal of an unintended potential level. When the switch element 60 is turned on in the period from the time T1 to the time T2, through-current flows from the power wire PW to the grounding wire GND in the CMOS inverter included in the circuit block 70, as described with reference to FIG. 1.

Next, a period from a time T2 to a time T3 is described. In the time T2, when the potential level of the first reset signal rd outputted from the first time constant circuit 10 reaches a threshold Vth1 of the Schmitt trigger circuit 20, the Schmitt trigger circuit 20 switches the output level to the L level. Thus, the reset mode of the processor 30 is cancelled, and the processor 30 starts a processing for determining the logical value of the internal control signal cnt1. In the embodiment, when the reset mode is cancelled, the processor 30 outputs the internal control signal cnt1 for turning off the switch element 60, which is, in this case, the internal control signal cnt1 of the L level. A time when the processor 30 determines the internal control signal cnt1 is the time T3.

When the potential level of the internal reset signal res is switched to the L level, the reset mode of the flip-flop circuit 40 is cancelled. When the potential level of the set terminal S is turned to the L level with the reset mode of the flip-flop circuit 40 released, the control signal cnt2 of the L level is outputted from the output terminal Q, and when the potential level of the set terminal S is turned to the H level, the control signal cnt2 of the H level is outputted from the output terminal Q. As described above, since the logical value of the internal control signal cnt1 outputted from the processor 30 is not determined before the time T3, the logical value of the control signal cnt2 outputted from the flip-flop circuit 40 is not determined as well. When the control signal cnt2 is turned to the H level, the switch control signal sw is turned to the L level, the switch element 60 is turned on and current flows into the circuit block 70.

Next, a period following the time T3 is described. At the time T3, the processor 30 determines the internal control signal cnt1 as being the L level. As a result, the flip-flop circuit 40 receives the internal control signal cnt2 of the L level through the set terminal S and outputs the control signal cnt2 of the L level through the output terminal Q. The inverter 50 receives the control signal cnt2 of the L level and outputs the switch control signal sw of the H level. Upon receiving the switch control signal sw of the H level, the switch element 60 is turned off. As a result, the circuit block 70 is decoupled from the power wire PW, and power is not consumed in the circuit block 70. Thereafter, normal operation is started, and in the period from a time T5 to a time T6 where operation of the circuit block 70 is requested, the processor 30 outputs the internal control signal cnt1 of the H level. When the internal control signal cnt1 is turned to the H level, the control signal cnt2 is also turned to the H level, the switch control signal sw is turned to the L level, the switch element 60 is turned on, and current is supplied into the circuit block 70.

As illustrated in FIG. 7, even when the electronic circuit 2 is reset with the first reset signal rc1 outputted from the first time constant circuit 10, possibility that the switch element 60 is turned on in the period from the time T1 to the time T2 is not removed. When the switch element 60 is turned on in the period from the time T1 to the time T2, dispensable leak current may be generated in the circuit block 70 due to insufficient rise of the potential of the power wire PW. Also, in the period from the time T2 to the time T3 when the processor 30 determines the internal control signal cnt1, the switch element 60 may be turned on, and thereby dispensable current may be consumed in the circuit block 70.

It is an object of the present disclosure to suppress the possibility of causing dispensable power consumption and malfunction in the electronic circuit 2 using the first reset signal rc1 when starting power supply.

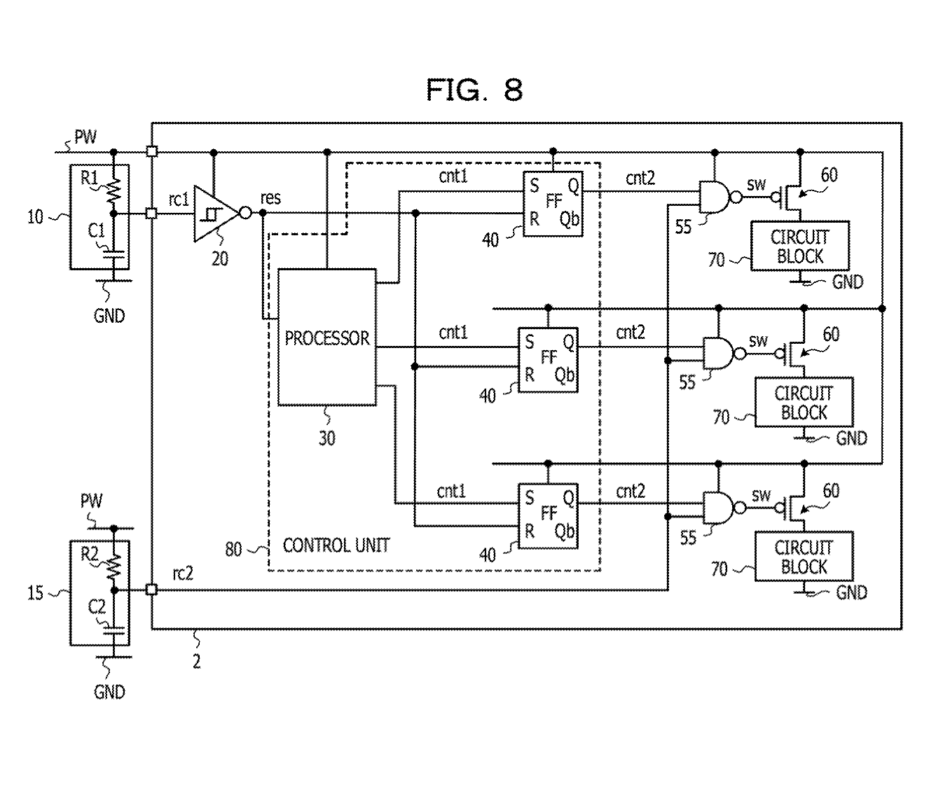

FIG. 8 is a diagram illustrating a circuit configuration example of the electronic circuit 2 according to the first embodiment. A component identical with a component illustrated in FIG. 5 is assigned with the same reference numeral, and description thereof is omitted or simplified. The electronic circuit 2 includes a Schmitt trigger circuit 20, a processor 30, a flip-flop circuit 40, a gate element 55, a switch element 60 and a circuit block 70. Those components included in the electronic circuit 2 receive power supply from a battery 3 or a power generation element 4 via a power wire PW. A first time constant circuit 10 is coupled to the power wire PW, and a first reset signal rc1 outputted from the first time constant circuit 10 is inputted into the Schmitt trigger circuit 20.

A second time constant circuit 15 is coupled to the power wire PW, and a second reset signal rc2 outputted from the second time constant circuit 15 and a control signal cnt2 outputted from the flip-flop circuit 40 are inputted into the gate element 55. The gate element 55 is, for example, a NAND circuit, and when the second reset signal rc2 is at the L level, outputs the switch control signal sw of the H level to control the switch element 60 in the off state. The time constant of the second time constant circuit 15 is set to a value larger than the time constant of the first time constant circuit 10. The second time constant circuit 15 includes a resistance element R2 and a capacity element C2.

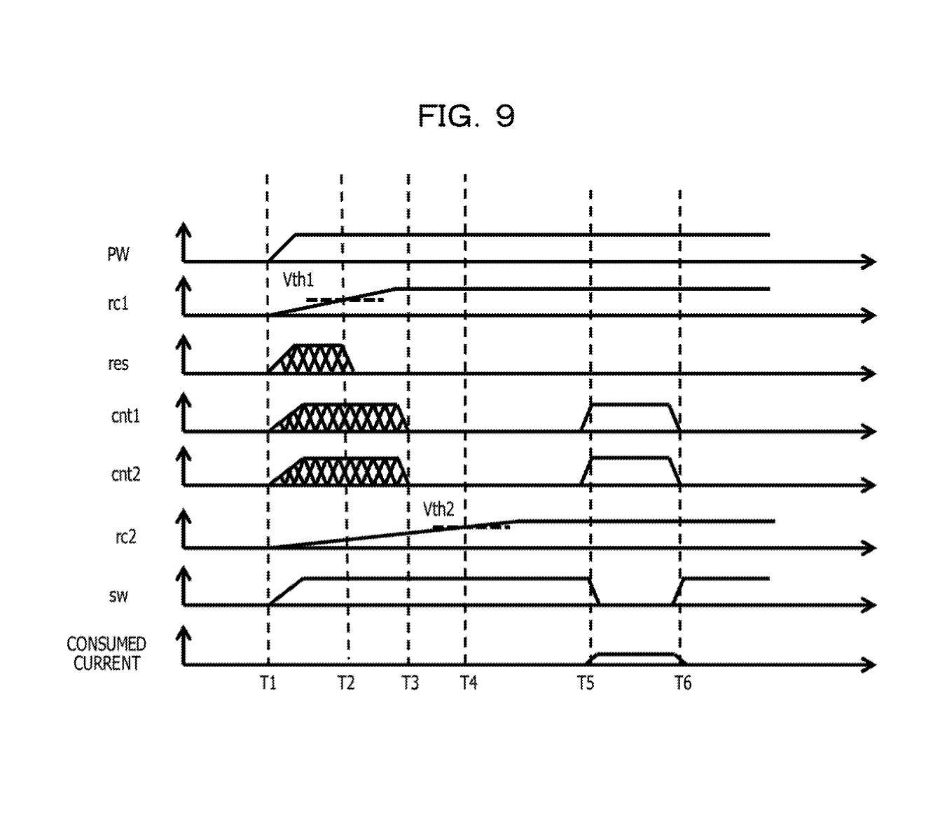

FIG. 9 is a timing chart, when power supply starts and in subsequent normal operations, for each of a potential of the power wire PW, a potential of the first reset signal rc1, a potential of the internal reset signal res, a potential of the internal control signal cnt1, a potential of the control signal cnt2, a potential of the second reset signal rc2 outputted from the second time constant circuit 15, a potential of the switch control signal sw, and current consumed in the circuit block 70. The potential of the power wire PW, the potential of the first reset signal rc1, the potential of the internal reset signal res, the potential of the internal control signal cnt1, and the potential of the control signal cnt2 are the same as those illustrated in FIG. 5. Here, behavior of the current consumed by the second reset signal rc2, the switch control signal sw outputted from the gate element 55 and the circuit block 70 is described.

When power supply to the power wire PW starts at the time T1, the potential of the second reset signal rc2 outputted from the second time constant circuit 15 increases gradually. Since the time constant of the second time constant circuit 15 is set larger than the time constant of the first time constant circuit 10, the potential of the second reset signal rc2 rises more gradually than the first reset signal rc1. The time T4 when the second reset signal rc2 reaches a threshold voltage Vth2 of the gate element 55 is set as a time later than the time T2 when the potential of the first reset signal rc1 reaches a threshold voltage Vth1 of the Schmitt trigger circuit 20. Further, the time T4 is set as a time later than the time T3 when the processor 30 determines the internal control signal cnt1 and the flip-flop circuit 40 determines the control signal cnt2. Although the logical value of the control signal cnt2 is not fixed in a period from the time T1 to the time T3, the switch control signal sw is turned to the H level irrespective of the logical value of the control signal cnt2 since the second reset signal rc2 of the L level is inputted into the gate element 55 during that period. As a result, the switch element 60 is maintained in the off state, power is not supplied to the circuit block 70, and current dispensable consumed in the circuit block 70 is suppressed. Thereafter, when the potential level of the second reset signal rc2 exceeds the threshold voltage Vth2 of the gate element 55 at the time T4, the logical value of the switch control signal sw outputted from the gate element 55 is determined by the logical value of the control signal cnt2. Specifically, if the control signal cnt2 is at the H level, the switch control signal sw is turned to the L level and the switch element 60 is turned on, and thereby power is supplied to the circuit block 70. On the other hand, if the control signal cnt2 is at the L level, the switch control signal sw is turned to the H level and the switch element 60 is turned off, and thereby power supply to the circuit block 70 is stopped.

Thus, according to the embodiment, in the device suppressing power consumption and malfunction by using the first reset signal rd. when power supply starts, the second time constant circuit 15 is provided in the power wire PW in order to further suppress power consumption and malfunction. The time constant of the second time constant circuit 15 is set to a value larger than the time constant of the first time constant circuit 10. Then, the switch control signal sw is kept at a predetermined logical value based on the second reset signal rc2 in a period including a reset period by the first reset signal rd (period from time T1 to time T2 in FIG. 9) and a period in which the processor 30 determines the output logical value (period from time T2 to time T3 in FIG. 9). This reduces a possibility that the switch element 60 may be turned on by error when power supply starts.

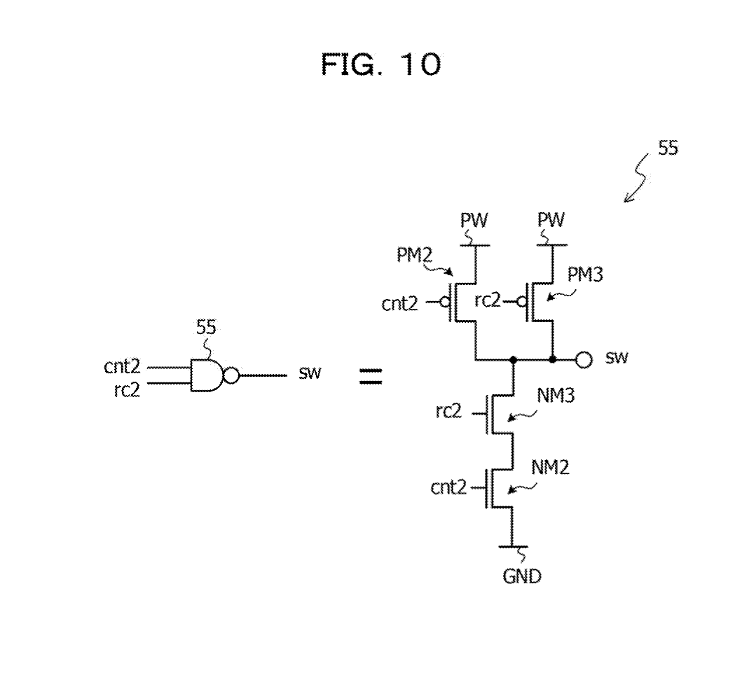

FIG. 10 is a diagram illustrating a circuit configuration example of the gate element 55. The gate element 55 is, for example, a two-input NAND circuit which outputs the switch control signal sw upon receiving the control signal cnt2 and the second reset signal rc2. The two-input NAND circuit includes a first P type MOS transistor PM2 and a second P type MOS transistor PM3, which are coupled in parallel with each other with respect to the power wire PW, and a first N type MOS transistor NM2 and a second N type MOS transistor NM3, which are coupled in series with each other with respect to the grounding wire GND. The control signal cnt2 is inputted into a gate electrode of the first P type MOS transistor PM2, and the second reset signal rc2 is inputted into a gate electrode of the second P type MOS transistor PM3. The control signal cnt2 is inputted into a gate electrode of the first N type MOS transistor NM2, and the second reset signal rc2 is inputted into a gate electrode of the second N type MOS transistor NM3. If the second reset signal rc2 is at the L level, the second P type MOS transistor PM3 is turned on and the second N type MOS transistor NM3 is turned off, and thereby the switch control signal sw is turned to the H level.

Here, in order to suppress the possibility that the gate element 55, which receives the second reset signal rc2 of the L level, outputs the switch control signal sw of the L level by error, the absolute value of a threshold voltage with which the second P type MOS transistor PM3 is switched from the off state to the on state may be set smaller than the absolute value of a threshold voltage with which the second N type MOS transistor NM3 is switched from the off state to the on state. By setting the threshold voltage of the second P type MOS transistor PM3 and the threshold voltage of the second N type MOS transistor NM3 in such a manner, turning on the second N type MOS transistor NM3 and turning off the second P type MOS transistor PM3 by the second reset signal rc2 of the L level by error may be reduced.

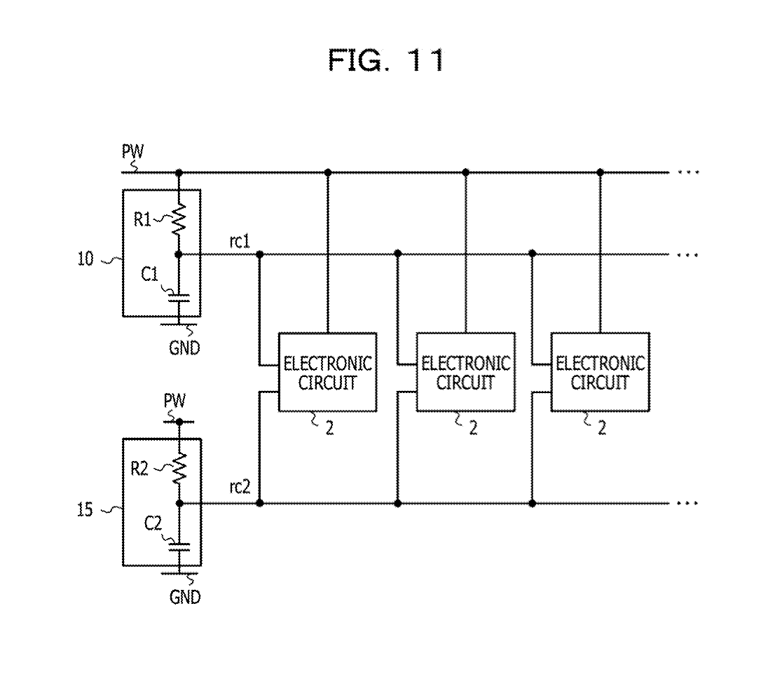

FIG. 11 is a diagram illustrating a coupling example when the first time constant circuit 10 and the second time constant circuit 15 are commonly provided in multiple electronic circuits 2. For example, in a case where multiple electronic circuits 2 are mounted on the same board and each of the multiple electronic circuits 2 is provided with the first time constant circuit 10 and the second time constant circuit 15, the number of components mounted on the board increases. In such a case, the first time constant circuit 10 and the second time constant circuit 15 may be provided commonly to the multiple electronic circuits 2, as illustrated in FIG. 11. Each of the multiple electronic circuits 2 includes, for example, a CPU, a SRAM, a flash memory, a sensor, a radio device, and so on.

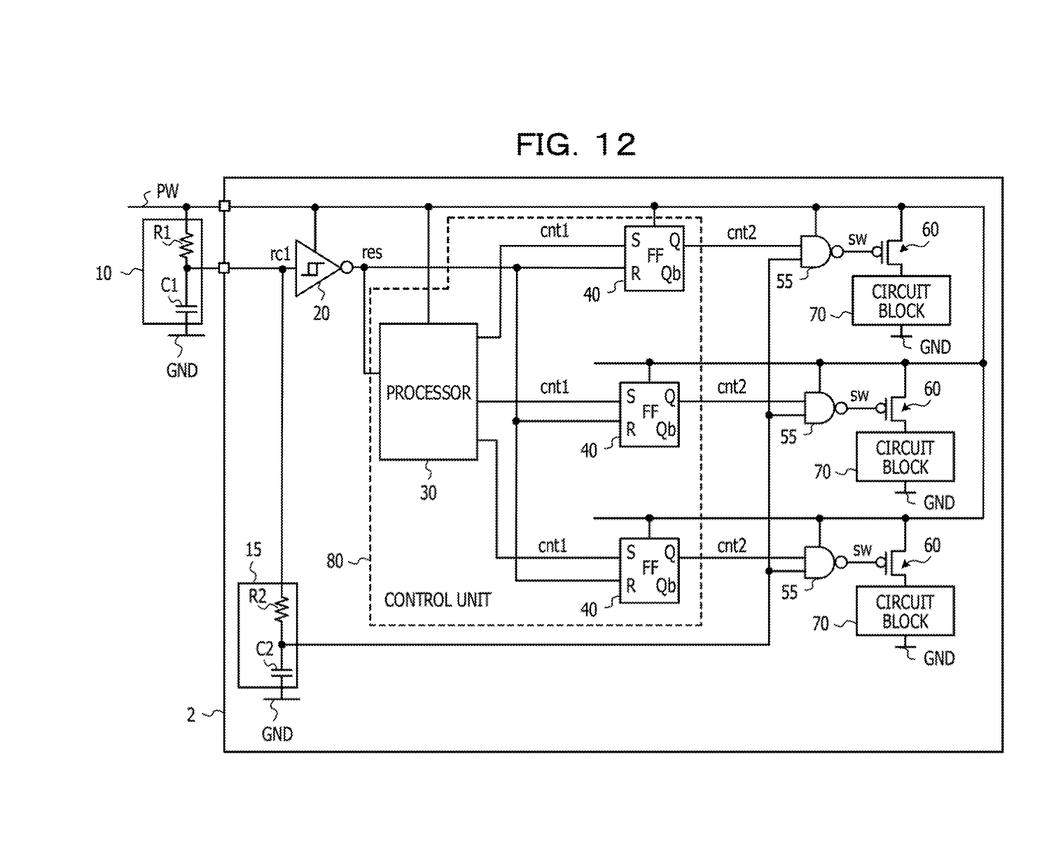

FIG. 12 is a diagram illustrating a modified example of the electronic circuit 2 according to the first embodiment. In FIG. 8, an example of the second time constant circuit 15 coupled in series with the power wire PW is illustrated. In FIG. 12, the second time constant circuit 15 may be coupled to an input line of the Schmitt trigger circuit 20. With such configuration, it is possible to generate the second reset signal rc2 having a further specific change delay with respect to a potential change of the first reset signal rc1. In this case, the second time constant circuit 15 may be provided inside the electronic circuit 2.

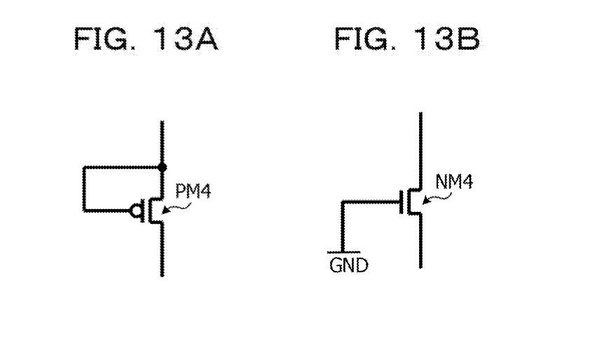

FIGS. 13A and 13B are diagrams illustrating a configuration example of a resistance element R1 or a resistance element R2. As illustrated in FIG. 13A, a P type MOS transistor PM4 with a gate electrode and a source electrode coupled to each other may be used as the resistance element R1 or the resistance element R2. As illustrated in FIG. 13B, an N type MOS transistor NM4 with a gate electrode coupled to a grounding wire GND may be used as the resistance element R1 or the resistance element R2. In either case, an off resistance of the MOS transistor is used as the resistance element R1 or the resistance element R2.

In the above, the first embodiment is described. The circuit configuration disclosed in the first embodiment is an example for implementing the embodiment and may be implemented by using the other circuit configuration. For example, the first time constant circuit 10 and the second time constant circuit 15 are not limited to a RC time constant circuit, but may be, for example, a RL time constant circuit using a capacity element R and an inductor element L. Although described as being a circuit which outputs the internal reset signal res inverse to the first reset signal rc1, the Schmitt trigger circuit 20 may be a circuit which outputs the internal reset signal res of a phase same as the first reset signal rc1. Further, in place of the Schmitt trigger circuit 20, an inverter or a buffer circuit not having a hysteresis characteristic may be used. The circuit configuration of the flip-flop circuit 40 illustrated in FIGS. 6A and 6B is just an example. If the circuit is configured to fix the value of the output terminal Q when a signal of a specific logical value is inputted into the reset terminal R and the circuit is a latch circuit which is capable of controlling the value of the output terminal Q with a signal inputted into the set terminal S when the reset mode is cancelled, the other circuit configuration may be used. The gate element 55 is not limited to the NAND circuit, and the other gate terminal such as the AND circuit and the NOR circuit may be used. The switch element 60 is not limited to the P type MOS transistor, and the N type MOS transistor and the other element having a switch function may be used. Further, in place of the circuit block 70, the other circuit block may be used as an internal circuit for saving power consumption.

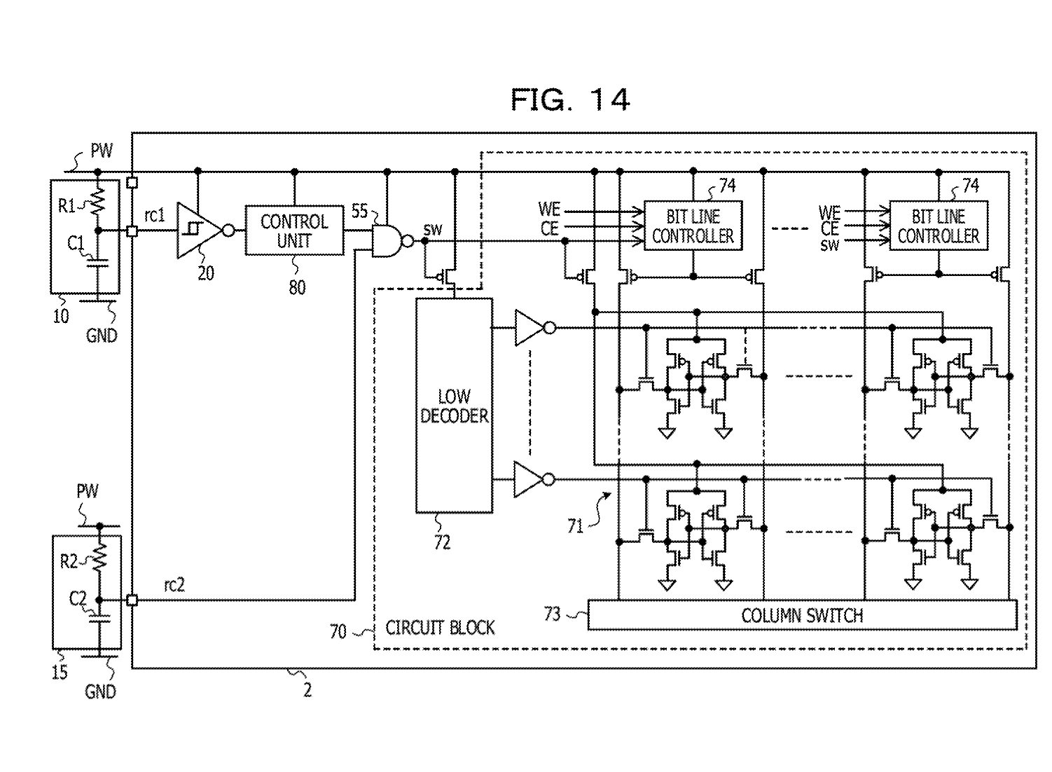

FIG. 14 is a diagram illustrating a circuit configuration example of the SRAM cell array used as the circuit block 70 in the first embodiment. The circuit block 70 includes a memory cell array 71 with the SRAM cell provided on the array. The circuit block 70 also includes a row decoder 72, a column switch 73 and a bit line controller 74. The bit line controller 74 receives a write enable signal WE, a chip enable signal CE and a switch control signal sw. In a predetermined period when a device 1 is in normal operation, power is supplied to the circuit block 70 by the switch control signal sw, and thereby writing of data into the SRAM cell, holding of data and reading of data is enabled.

### Second Embodiment

In the second embodiment, a discharge path is provided in the signal line of the second reset signal rc2 in addition to the configuration of the electronic circuit 2 disclosed in FIG. 12. In the circuit configuration disclosed in the first embodiment, when power supply to the power wire PW is stopped, the potential of the first reset signal rc1 and the potential of the second reset signal rc2 gradually drop according to the time constant of the first time constant circuit and the time constant of the second time constant circuit respectively. In this case, if power supply to the power wire PW is resumed before the potential of the first reset signal rc1 and the potential of the second reset signal rc2 drop to the L level, the initial operation described in the first embodiment may not be performed normally. In the second embodiment, after power supply to the power wire PW is stopped and before power supply to the power wire PW is resumed, the charge in the signal line of the first reset signal rc1 and the change and the charge in the signal line of the second reset signal rc2 are discharged to the grounding wire GND.

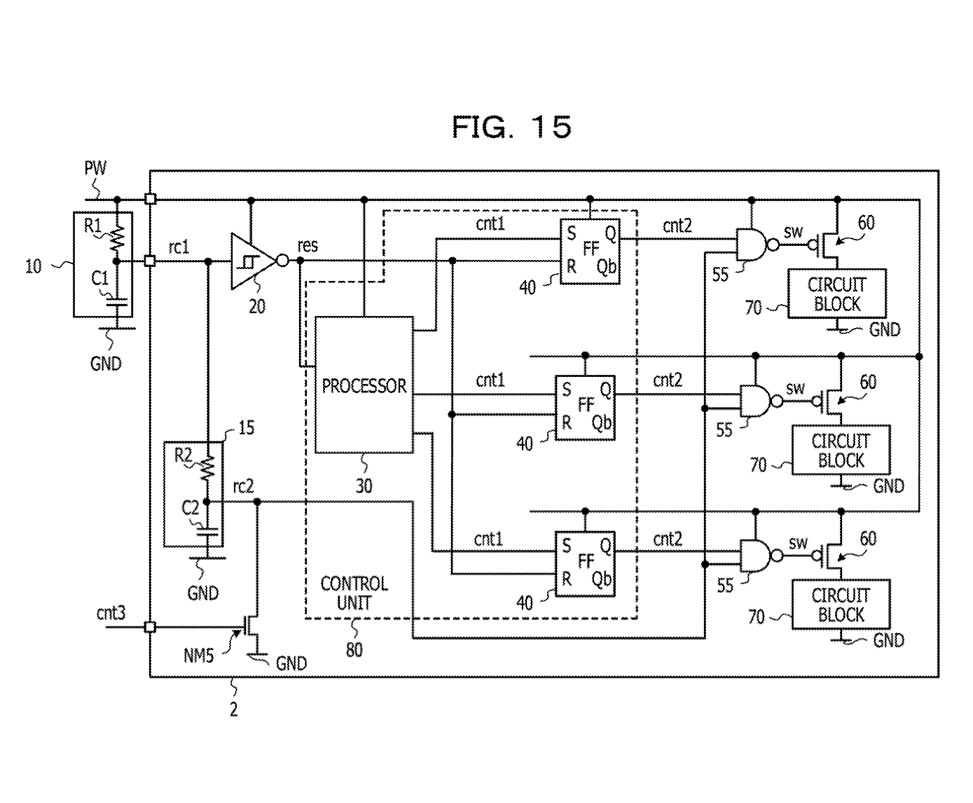

FIG. 15 is a diagram illustrating a circuit configuration example of the electronic circuit 2 according to the second embodiment. A component identical with a component illustrated in FIG. 12 is assigned with the same reference numeral, and description thereof is omitted or simplified. The signal line of the second reset signal rc2 outputted from the second time constant circuit 15 and the grounding wire GND are coupled with each other via an N type MOS transistor NM5 being the discharge element. The gate electrode of the N type MOS transistor NM5 receives the discharge element control signal cnt3. The discharge element control signal cnt3 is controlled so as to be turned to the H level when power supply to the power wire PW is stopped. When power supply to the power supply line PW is stopped and thereby the discharge element control signal cntr3 is turned to the H level, the N type MOS transistor NM5 is turned on and the charge stored in the capacity element C2 of the second time constant circuit 15 is discharged toward the grounding wire GND. Thus, drop speed of the potential of the second reset signal rc2 is improved. Further, the charge stored in the capacity element C1 of the first time constant circuit 10 is also discharged to the grounding wire GND via the resistance element R2 and the N type MOS transistor NM5. Thus, drop speed of the potential of the first reset signal rc1 is improved.

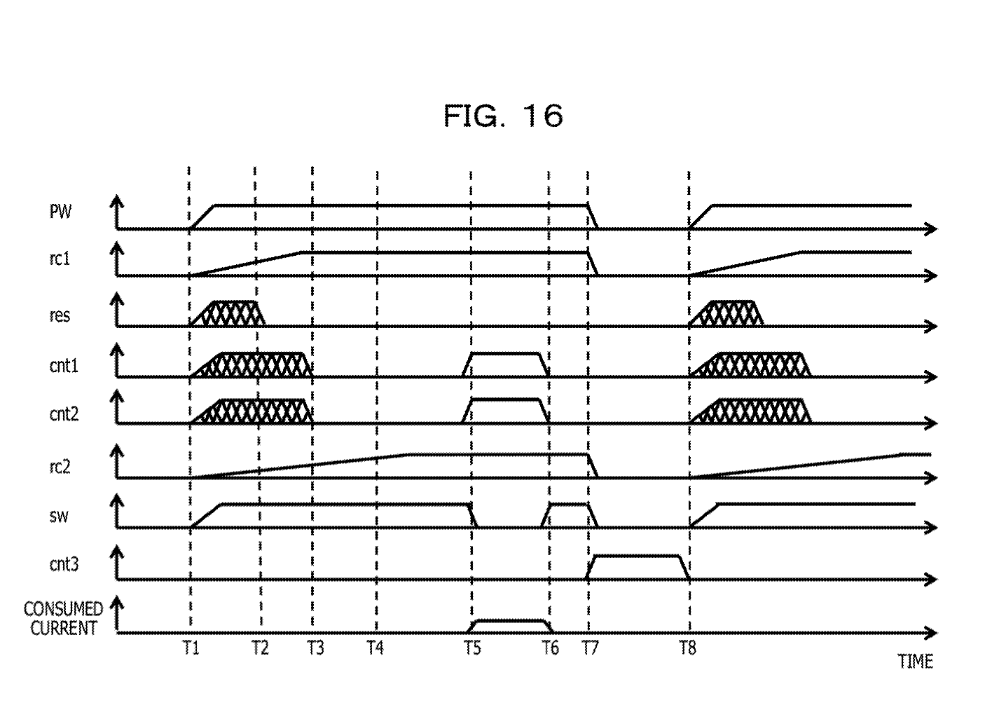

FIG. 16 is a timing chart, in the second embodiment, for each of a potential of the power wire PW, a potential of the first reset signal rc1, a potential of the internal reset signal res, a potential of the internal control signal cnt1, a potential of the control signal cnt2, a potential of the second reset signal rc2, a potential of the switch control signal sw, a potential of the discharge element control signal cnt3, and current consumed by the circuit block 70. In a period from the time T1 to the time T6, potentials other than the potential of the discharge element control signal cnt3 are same as those illustrated in the timing chart disclosed in FIG. 9. The discharge element control signal cnt3 is maintained at the L level for a period from the time T1 to the time T7.

At the time T1, power supply to the power wire PW is stopped and the potential of the power wire PW drops. On the other hand, the potential of the discharge element control signal cnt3 changes to the H level at the time T7. Thus, the N type MOS transistor NM5 is turned on, and the potential of the first reset signal rc1 and second reset signal rc2 changes to the L level. Also, the switch control signal sw is turned to the L level. Thereafter, when power supply to the power wire PW is started again at the time T8, the potential of each node changes in the same manner as in the period after the time T1, and reset operation is executed again.

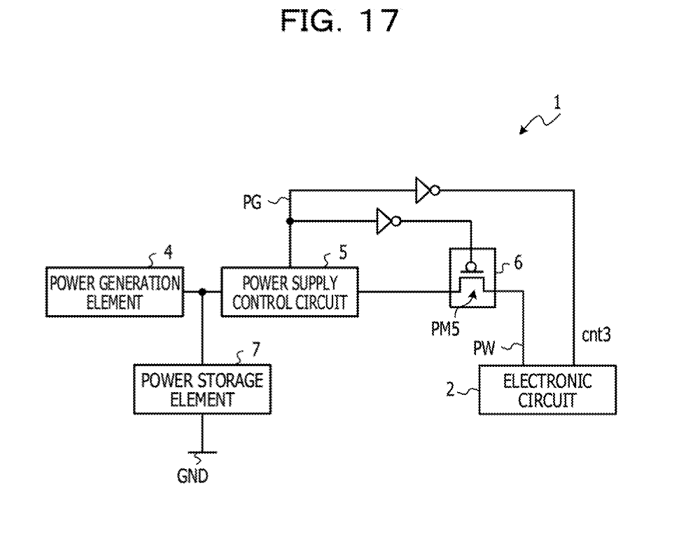

FIG. 17 is a diagram illustrating an example of a method for generating the discharge element control signal cnt3. In FIG. 16, an entire configuration example of the device 1 including the electronic circuit 2 and the power generation element 4 is illustrated, in which a power supply control circuit 5 controls a switch 6. Here, an example of the switch 6 formed by the P type MOS transistor PM5 is illustrated.

When the charge is fully stored in the power storage element 7, the power supply control circuit 5 outputs a power good signal PG. An inversion signal of the power good signal PG controls the P type MOS transistor PM5 in the on state, and thereby power is supplied to the power wire PW. The inversion signal of the power good signal PG is supplied to the electronic circuit 2 as the discharge element control signal cnt3. The discharge element control signal cnt3 turns off the N type MOS transistor NM5 in the electronic circuit 2 illustrated in FIG. 15, and thereby the discharge path is shut off.

The power supply control circuit 5 stops output of the power good signal PG when amount of the charge stored in the power storage element 7 is reduced by operation of the electronic circuit 2 and thereby maintaining the power wire PG at a predetermined potential becomes difficult. Thus, the P type MOS transistor PM5 is turned off and thereby power supply to the electronic circuit 2 is stopped. On the other hand, the discharge element control signal cnt3 controls the N type MOS transistor NM5 in the on state, and thereby charges of the capacity element C1 of the first time constant circuit 10 and the capacity element C2 of the second time constant circuit RC2 are discharged and the first reset signal rd and the second reset signal rc2 are turned to the L level.

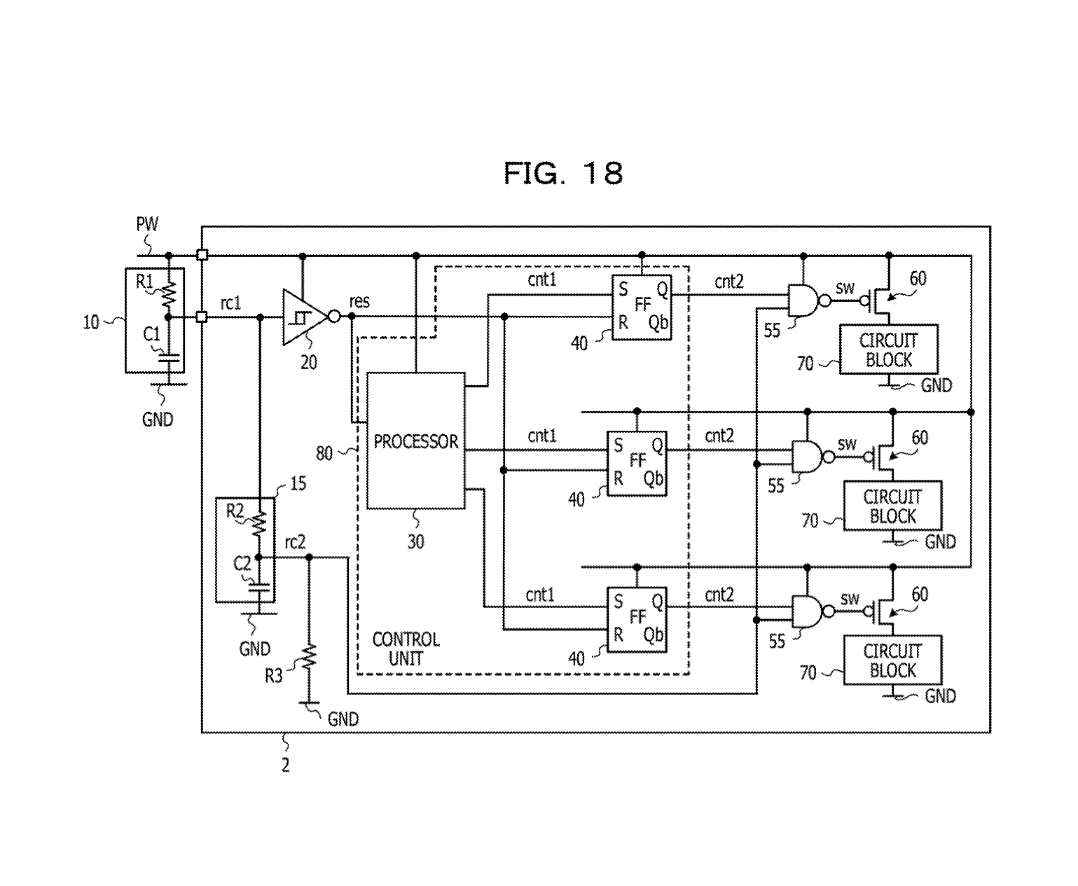

FIG. 18 is a diagram illustrating a modified example of the electronic circuit 2 in the second embodiment. Although in the example illustrated in FIG. 15, the N type MOS transistor NM5 is used as the discharge element, a resistance element R3 is used as the discharge element in this modified example. In the modified example, the discharge element control signal cnt3 is not requested, but a current path passing via resistance elements R1, R2, and R3 exists between the power wire PW and the grounding wire GND. For example, assuming that resistance value of the resistance element R1 is 100 kΩ, resistance value of the resistance element R2 is 100 MS2 and resistance value of the resistance element R3 is 1 MΩ, and potential of the power wire PW is 1.8 V, leak current of about 18 nA is generated. Resistance values of resistance elements R1, R2, and R3 are set in consideration of the magnitude of the leak current and the discharge rate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A circuit comprising:
a power wire;
a switch element coupled to the power wire;
an internal circuit coupled to the power wire via the switch element;
a signal generation circuit coupled to the power wire and configured to generate a control signal based on a first reset signal outputted for a first period after power supply from a power source to the power wire starts; and
a gate element configured to control the switch element based on the control signal and a second reset signal outputted for a second period longer than the first period after the power supply to the power wire starts.

2. The circuit according to claim 1, wherein
the first reset signal is generated by a first time constant circuit coupled to the power wire,
the second reset signal is generated by a second time constant circuit coupled to the power wire, and
a second time constant of the second time constant circuit is larger than a first time constant of the first time constant circuit.

3. The circuit according to claim 1, wherein
the first reset signal is generated by a first time constant circuit coupled to the power wire, and
the second reset signal is generated by a second time constant circuit coupled to a signal line through which the first reset signal is transmitted.

4. The circuit according to claim 1, wherein
the signal generation circuit includes:
an arithmetic circuit configured to receive the power supply from the power wire and generate an internal signal based on the first reset signal; and
a latch circuit configured to receive the power supply from the power wire and generate the control signal based on the first reset signal and the internal signal.

5. The circuit according to claim 4, wherein the first reset signal causes the control signal outputted from the latch circuit to be fixed to a logical value for keeping the switch element in off state for the first period determined by the first time constant after the power supply to the power wire starts.

6. The circuit according to claim 1, wherein
the gate element is a NAND circuit,
the NAND circuit includes a first P type MOS transistor and a first N type MOS transistor, the first P type MOS transistor is coupled to the power wire and configured to receive the second reset signal, and the first N type MOS transistor is coupled to a grounding wire and configured to receive the second reset signal,
an absolute value of a first threshold of the first P type MOS transistor is smaller than an absolute value of a second threshold of the first N type MOS transistor, and
the switch element is a second P type MOS transistor provided between the power wire and the internal circuit.

7. The circuit according to claim 5, wherein after the first reset signal is stopped and before the second reset signal is stopped, the arithmetic circuit keeps the logical value of the control signal such that the switch element is kept in the off state based on the control signal outputted from the latch circuit.

8. The circuit according to claim 2, wherein
the first time constant circuit includes a first resistance element and a first capacity element, and
the second time constant circuit includes a second resistance element and a second capacity element.

9. The circuit according to claim 2, wherein
the first time constant circuit is provided outside the electronic circuit, and
the second time constant circuit is provided inside the electronic circuit, and coupled to the first time constant circuit.

10. The circuit according to claim 8, further comprising a discharge element coupled to the second time constant circuit and configured to discharge charge stored in the second capacity element.

11. The circuit according to claim 10, wherein the discharge element discharges the charge stored in the second capacity element when the power supply to the power wire stops.

12. A method of controlling a circuit including a power wire coupled to a power source, an internal circuit coupled to the power wire via a switch element, a signal generation circuit coupled to the power wire and configured to generate a control signal to control the switch element, the method comprising:
generating, by a first time constant circuit coupled to the power wire, a first reset signal for a first period after power supply to the power wire starts;
fixing the control signal in a certain logical value using the first reset signal;
generating, by a second time constant circuit coupled to the power wire, a second reset signal for a second period longer than the first period after the power supply to the power wire starts; and
invalidating controlling of the switch element by the control signal using the second reset signal.

13. The method according to claim 12, wherein
a second time constant of the second time constant circuit is larger than a first time constant of the first time constant circuit.

14. The method according to claim 12, wherein
the second time constant circuit is coupled to a signal line through which the first reset signal is transmitted.

15. A device comprising:
a power source;
a power wire coupled to the power source;
a first time constant circuit coupled to the power wire and configured to output a first reset signal for a first period after power supply to the power wire starts;
a second time constant circuit coupled to the power wire and configured to output a second reset signal for a second period longer than the first period after the power supply to the power wire starts;
a switch element coupled to the power wire;
an internal circuit coupled to the power wire via the switch element;
a signal generation circuit coupled to the power wire and configured to generate a control signal to control the switch element based on the first reset signal; and
a gate element configured to control the switch element based on the control signal and the second reset signal.

16. The device according to claim 15, wherein
a second time constant of the second time constant circuit is larger than a first time constant of the first time constant circuit.

17. The device according to claim 15, wherein
the second time constant circuit is coupled to a signal line through which the first reset signal is transmitted.

18. The device according to claim 15, wherein
the signal generation circuit includes:
an arithmetic circuit configured to receive the power supply from the power wire and generate an internal signal based on the first reset signal; and
a latch circuit configured to receive the power supply from the power wire and generate the control signal based on the first reset signal and the internal signal.

19. The device according to claim 18, wherein the first reset signal causes the control signal outputted from the latch circuit to be fixed to a logical value for keeping the switch element in off state for the first period determined by the first time constant after the power supply to the power wire starts.

20. The device according to claim 15, wherein
the gate element is a NAND circuit,
the NAND circuit includes a first P type MOS transistor and a first N type MOS transistor, the first P type MOS transistor is coupled to the power wire and configured to receive the second reset signal, and the first N type MOS transistor is coupled to a grounding wire and configured to receive the second reset signal,
an absolute value of a first threshold of the first P type MOS transistor is smaller than an absolute value of a second threshold of the first N type MOS transistor, and
the switch element is a second P type MOS transistor provided between the power wire and the internal circuit.
